(19) United States
(12) Patent Application Publication
(10) Pub. No.: US 2016/0376144 A1
(43) Pub. Date: Dec. 29, 2016

(54) Apparatus and Method For Protecting a Micro-Electro-Mechanical System

(71) Applicant: W. L. Gore & Associates, Inc., Newark, DE (US)

(72) Inventor: Andrew J. Holliday, Wilmington, DE (US)

(21) Appl. No.: 14/791,955

(22) Filed: Jul. 6, 2015

Related U.S. Application Data
(60) Provisional application No. 62/021,303, filed on Jul. 7, 2014.

(51) Int. Cl. B81B 7/00; H04R 1/08; B81C 1/00

(52) U.S. Cl. CPC B81B 7/0038; B81C 1/00285; H04R 1/086; B81B 2201/0271

(57) ABSTRACT

A protective cover for a micro-electro-mechanical system that has a low mass/area, preferably <3 gsm, most preferably <1 gsm.

### BACKGROUND OF THE INVENTION

The integration of mechanical elements, sensors, actuators or the like and electronics on a common silicon substrate through micro-fabrication technology is known as micro-electro-mechanical system (“MEMS”). MEMS sensors may be used in microphones, consumer pressure sensor applications, tire pressure monitoring systems, gas flow sensors, accelerometers, and gyroscopes.

A known silicon condenser microphone MEMS package includes an acoustic transducer and acoustic port. The acoustic port further includes an environmental barrier such as polytetrafluoroethylene (PTFE) or a sintered metal to protect the transducer from environmental elements such as sunlight, moisture, oil, dirt, and/or dust. Acoustic transducers include speakers and microphones.

Expanded PTFE (ePTFE) membranes have been used for protecting acoustic transducers for many years. Recently, several applications for protecting ultrasonic transducers have come out. Two examples are: (1) a transmitter, and possibly receiver, of short ultrasonic pulses for gesture recognition (alternatively, standard acoustic microphones can be used to receive the signal) and or proximity sensing. The time of flight of these pulses are used to determine the 3D location of a hand/finger and or distance to an object; (2) a MEMS digital loudspeaker. The latter is created with an array of ultrasonic transmitters that create ultrasonic pulses which digitally recreate an audible signal.

The difference in intended frequency transmission between acoustic (audible) and ultrasonic applications require different membrane properties for any protective cover. When transmitting near or below the resonant frequency of a reactive protective cover, the stiffness/compliance of an ePTFE membrane is the material property which can be correlated to acoustic transmission. Typical non-ePTFE alternatives include silicone and urethane films for these applications. Above the resonance frequency of reactive protective cover, applicants have discovered that the mass/area of the membrane is the critical attribute that drives transmission. For that reason, a low mass ePTFE is desired.

A need also still exists for environmental protection and pressure equalization capability in a thin form factor as required by a MEMS package.

### SUMMARY

According to the present disclosure, a method of protecting a micro-electro-mechanical system having an ultrasonic transducer is provided by disposing adjacent to the ultrasonic transducer an expanded PTFE membrane having a mass/area ratio of about 3 g/m² or less. In preferred embodiments, the mass/area ratio is about 1 g/m² or less, the expanded PTFE membrane captures particles greater than about 0.25 microns in diameter, the expanded PTFE membrane provides transmission loss of less than about 3 dB at a frequency of about 50 to about 92.5 KHz, and the expanded PTFE membrane provides sonic transmission, particle capture, and pressure venting.

In another aspect, the disclosure provides a micro-electro-mechanical system comprising an ultrasonic transducer and an expanded PTFE protective cover having a mass/area ratio of about 3 g/m² or less disposed adjacent to the ultrasonic transducer.

In still another aspect, a method of protecting a micro-electro-mechanical system having an ultrasonic transducer is provided by disposing adjacent to the ultrasonic transducer a porous polymeric material that satisfies the relationship:

$$\frac{m}{A} < {10}^{( 3 / 5 )} \frac{{Z}_{air}}{2 π f} ;$$

where

Zair=Specific Acoustic Impedance of Air (rayls)=413;
m/A=Mass per area (kg/m²);
f=Frequency (Hz),
f>20 KHz

In alternative embodiments, the equation is:

$$\frac{m}{A} < {10}^{( 3 / 10 )} \frac{{Z}_{air}}{2 π f}$$

And in other alternatives:

$$\frac{m}{A} < {10}^{( 3 / 20 )} \frac{{Z}_{air}}{2 π f}$$

### BRIEF DESCRIPTION OF THE DRAWINGS

FIG. 1 is a schematic of the test method used to test an embodiment of the invention.

FIG. 2 is a plot of mass/area vs acoustic performance (amplification) for additional exemplary embodiments of the invention.

FIG. 3 is a scanning electron micrograph of an exemplary embodiment of the invention.

### DETAILED DESCRIPTION

In one embodiment, the present disclosure provides a protective cover for a micro-electro-mechanical system that has a low mass/area, preferably <3 gsm, most preferably <1 gsm. In another embodiment, the disclosure provides a method of protecting a micro-electro-mechanical system having an ultrasonic transducer comprising the step of disposing adjacent to said ultrasonic transducer an expanded PTFE membrane having a mass/area ratio of about 3 g/m² or less. In another embodiment, the disclosure provides a micro-electro-mechanical system comprising an ultrasonic transducer and an expanded FIFE protective cover having a mass/area ratio of about 3 g/m² or less disposed adjacent to said ultrasonic transducer. The present disclosure involves the use of a protective cover for a micro-electro-mechanical system that has a mass/area of <3 gsm, most preferably <1 gsm. Such a protective cover surprisingly functions both to keep particulate matter larger than about 0.25 microns away from the device protected, as well as allowing acoustic transmission with a loss of less than about 3 dB at a frequency range of about 50-92.5 KHz. The protective cover must also be durable enough to survive the packaging process, surface mount technology application, and through its intended use.

The protective cover is preferably a porous membrane of ePTFE, although non-porous membranes are used in the alternative. Suitable porous membranes in preferred embodiments are made according to the teachings of U.S. Pat. Nos. 3,953,566 and 7,306,729 to have the following properties: mass/area less than about 3 gsm, most preferably <1 gsm; machine direction matrix tensile strength greater than about 25 kpsi; transverse direction matrix tensile strength greater than about 30 kpsi; bubble point greater than about 30; a filtration effectiveness for 0.25 micron particles of at least about 99.9%; and a Gurley number of between about 1 and 2.

The mass/area of the membrane was calculated by measuring the mass of a well-defined area of the sample using a scale. The sample was cut to a defined area using a die or any precise cutting instrument. The Gurley air flow test measures the time in seconds for 100 cm³ of air to flow through a 6.45 cm² sample at 12.4 cm of water pressure. The samples were measured in a Gurley Densometer Model 4340 Automatic Densometer.

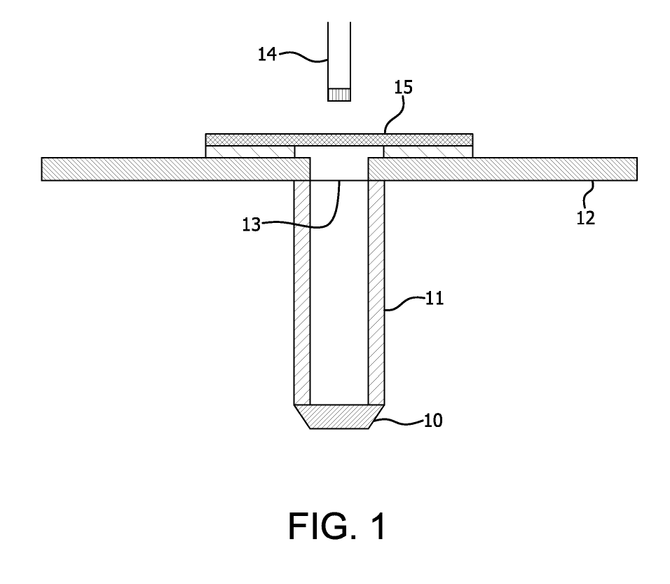

A sample of a porous membrane was constructed as described above. It had a mass/area of 1.2 g/m², a Gurley number of 1.1 seconds, and an acoustic loss of 1.8 dB at a frequency of 50-92.5 KHz. The testing method is described below in connection with FIG. 1.

With reference to FIG. 1, inside of an anechoic chamber, a Tannoy Super Tweeter ultrasonic speaker 10 is mounted vertically. PVC tubing 11 with a 1.5 inches diameter is sealed to the front of speaker 10. The other end of PVC tubing 11 is coupled to a wooden baffle 12 with a matching 1.5 inch diameter hole 13. A B&K4939 microphone 14 is mounted approximately 2 inches from the surface of wooden baffle 12. Speaker 10 is amplified with a B&K2716C amplifier, and the microphone is powered by a B&K NEXUS conditioning amplifier. After microphone 14 is calibrated and mounted, speaker 10 generates a stepped sweep from a 92.5 kHz tone to a 20 kHz tone at a 12^{th} octave step size. The sweep is generated with a constant 900 mV excitation voltage. Microphone 14 records the sound pressure level at each step, creating a curve recorded as the “open condition.” Membrane 15 is mounted to wooden baffle 12 using a ring of double-sided pressure sensitive adhesive with a 1 and ¾ inch inner diameter. The frequency sweep is then repeated, and the sound pressure at each frequency is again recorded. This curve is subtracted from the open condition to create an attenuation curve. The attenuation between 50-92.5 kHz is averaged to summarize the ultrasonic attenuation.

A third octave band centered around 60 KHz was chosen, the average amplification within this octave band is shown in Table 1 for a wide range of ePTFE membranes.

TABLE 1

| Mass | Amplification |
|---|---|
| (g/m²) | (dB) |
| 0.14 | −1.21875 |
| 0.3 | −0.01875 |
| 1 | −2.3 |
| 1.5 | −2.49375 |
| 1.6 | −3.31 |
| 2.7 | −4.97125 |
| 3.1 | −7.1125 |
| 3.5 | −7.13 |
| 3.7 | −7.9875 |
| 4.1 | −7.19 |
| 6 | −12.60375 |

According to the present disclosure, a method of protecting a micro-electro-mechanical system having an ultrasonic transducer is provided by disposing adjacent to the ultrasonic transducer a porous polymeric material that satisfies the relationship:

$$\frac{m}{A} < {10}^{( 3 / 5 )} \frac{{Z}_{air}}{2 π f} ;$$

where

Zair=Specific Acoustic Impedance of Air (rayls)=413;

m/A=Mass per area (kg/m²);
f=Frequency (Hz),
f>20 KHz
In alternative embodiments, the equation is

$$\frac{m}{A} < {10}^{( 3 / 10 )} \frac{{Z}_{air}}{2 π f}$$

And in other alternatives:

$$\frac{m}{A} < {10}^{( 3 / 20 )} \frac{{Z}_{air}}{2 π f}$$

The first equation covers an acoustic loss b/w 0-12 dB, the second equation: 0-6 dB, the third one 0-3 dB.

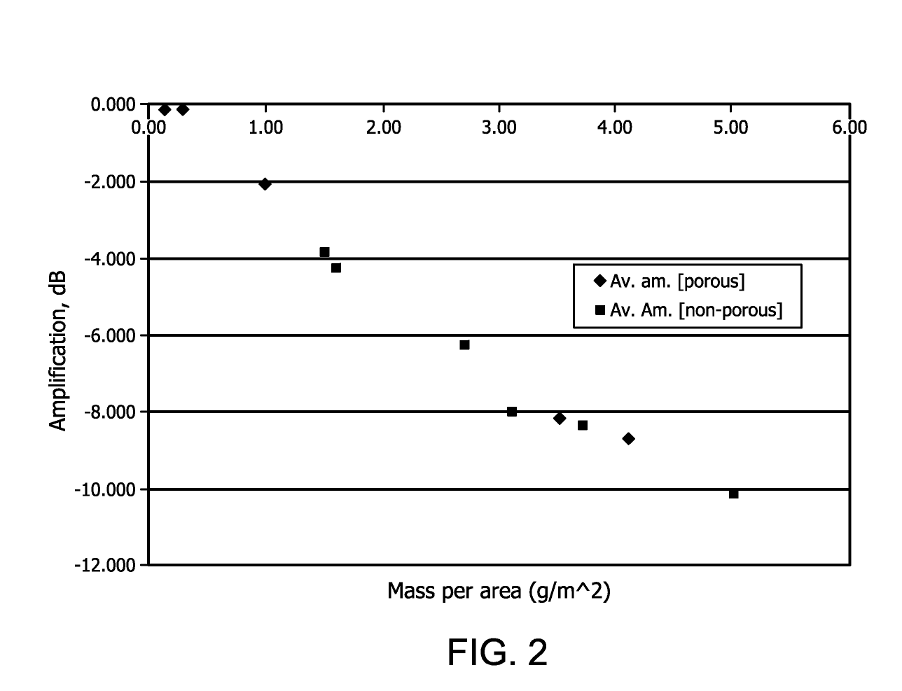

FIG. 2 is a plot of mass/area vs acoustic performance (amplification or acoustic loss) for additional exemplary embodiments of the disclosure.

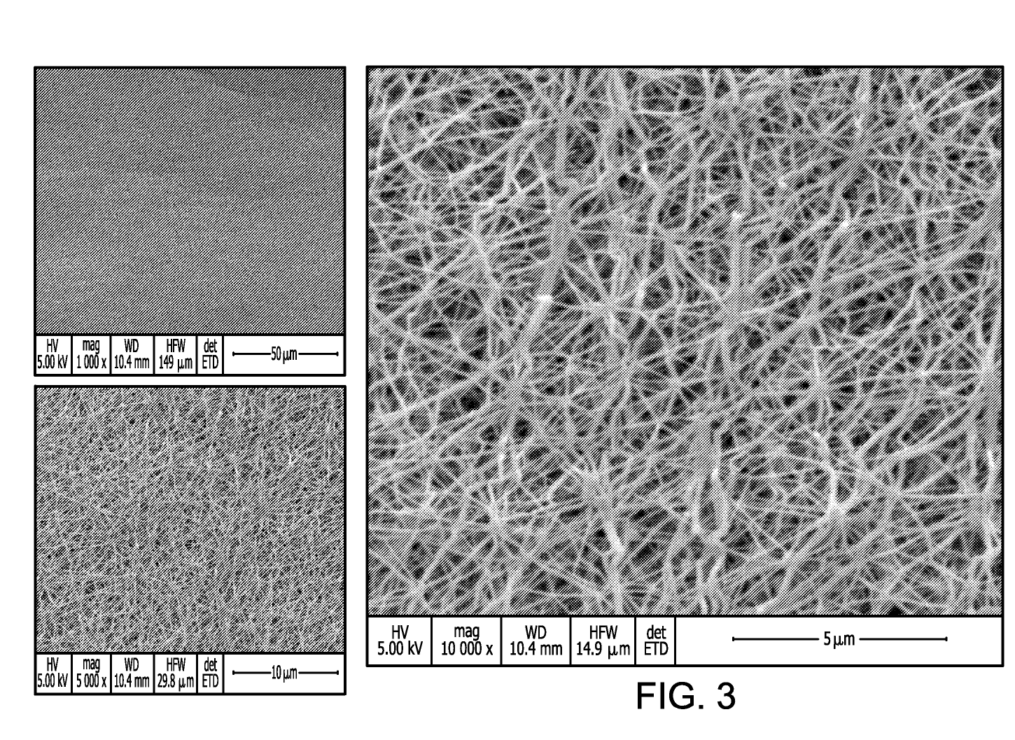

FIG. 3 is a scanning electron micrograph showing the microstructure an exemplary embodiment of the disclosure.

What is claimed is:

1. A method of protecting a micro-electro-mechanical system having an ultrasonic transducer comprising the step of disposing adjacent to said ultrasonic transducer an expanded PTFE membrane having a mass/area ratio of about 3 g/m² or less.

2. A method as defined in claim 1 wherein said mass/area ratio is about 1 g/m² or less.

3. A method as defined in claim 1 wherein said expanded PTFE membrane captures particles greater than about 0.25 microns in diameter.

4. A method as defined in claim 1 wherein said expanded PTFE membrane provides transmission loss of less than about 3 dB at a frequency of about 50 to about 92.5 KHz.

5. A method as defined in claim 1 wherein said expanded PTFE membrane provides sonic transmission, particle capture, and pressure venting,

6. A micro-electro-mechanical system comprising an ultrasonic transducer and an expanded PTFE protective cover having a mass/area ratio of about 3 g/m² or less disposed adjacent to said ultrasonic transducer.

7. A system as defined in claim 1 wherein said mass/area ratio is about 1 g/m² or less.

8. A system as defined in claim 1 wherein said expanded PTFE membrane captures particles greater than about 0.25 microns in diameter,

9. A system as defined in claim 1 wherein said expanded PTFE membrane provides transmission loss of less than about 3 dB at a frequency of about 50 to about 92.5 KHz.

10. A system as defined in claim 1 wherein said expanded PTFE membrane provides sonic transmission, particle capture, and pressure venting.

11. A method protecting a micro-electro-mechanical system having an ultrasonic transducer comprising the step of disposing adjacent to said ultrasonic transducer a porous polymeric material that satisfies the relationship:
$$\frac{m}{A} < {10}^{( 3 / 5 )} \frac{{Z}_{air}}{2 π f} ;$$
where
Zair=Specific Acoustic Impedance of Air (rayls)=413;
m/A=Mass per area (kg/m²);
f=Frequency (Hz),
f>20 KHz

12. A method as disclosed in claim 11 where said membrane is ePTFE.
